(19) United States
(12) Patent Application Publication
(10) Pub. No.: US 2026/0140183 A1
(43) Pub. Date: May 21, 2026

(54) ECCENTRICITY MEASUREMENT SYSTEM

(71) Applicant: HYUNDAI MOBIS CO., LTD., Seoul (KR)

(72) Inventor: Sanghan LEE, Yongin-si (KR)

(73) Assignee: HYUNDAI MOBIS CO., LTD., Seoul (KR)

(21) Appl. No.: 19/386,435

(22) Filed: Nov. 12, 2025

(30) Foreign Application Priority Data
Nov. 18, 2024 (KR) 10-2024-0164157
Nov. 18, 2024 (KR) 10-2024-0164159

(51) Int. Cl. G01R 31/34

(52) U.S. Cl. CPC G01R 31/343

(57) ABSTRACT

An eccentricity measurement system configured to measure eccentricity occurring in a motor rotor. The eccentricity measurement system may include an eccentricity measurement sensor mounted in a motor and configured to measure all tilt eccentricity, static eccentricity, and dynamic eccentricity of a rotor by using a change in magnetic field generated between the rotor and a stator, thereby overcoming a limitation of a reflective laser sensor method in the related art, reducing costs in comparison with the reflective laser sensor in the related art, detecting an eccentricity factor that most significantly affects noise and vibration of a rotary device, and detecting a defect at an initial stage of mass production.

### CROSS REFERENCE TO RELATED APPLICATION

The present application claims priority to Korean Patent Application No. 10-2024-0164159, filed on November 18, 2024, and Korean Patent Application No. 10-2024-0164157, filed on November 18, 2024, the entire contents of both are incorporated herein for all purposes by reference.

### BACKGROUND OF THE DISCLOSURE

### Technical Field of the Disclosure

The present disclosure relates to an eccentricity measurement system, and more particularly, to an eccentricity measurement system configured to measure eccentricity occurring in a motor rotor.

### Description of the Related Art

Reflective laser displacement sensors are being widely used for methods of measuring rotor eccentricities of permanent magnet electric motors. This method measures variations in distance by irradiating a rotary shaft directly with laser beams. The method has an advantage of being intuitively understandable and applicable to various rotary devices. In addition, transmissive micrometers or transmissive 2D micrometers are also used in industrial sites.

However, in case that an outer diameter of a rotor core other than a shaft is measured when a reflective laser displacement sensor in the related art is applied to a permanent magnet electric motor, a sensor needs to be mounted outside a housing of an electric motor, and a surface of the rotor core needs to be irradiated with laser beams. However, because the rotor core is covered by a stator in the structure of the electric motor, the laser beams cannot penetrate the rotor core, and the measurement cannot be performed. In particular, there is a problem in that it is difficult to measure static eccentricity because it is impossible to measure a radial displacement at a single point.

For this reason, at least two or more sensors are required to be provided on two opposite sides even though a portion of the shaft that is not covered by the stator core. In this case, the sensor may interfere with other external components, which imposes a restriction on a sensor mounting structure and leads to an increase in costs of the system.

### [Document of Related Art]

(Patent Document 1) Japanese Patent No. 6441757 "Eccentricity Direction Detection Device and Variable Gap Motor"

### SUMMARY OF THE DISCLOSURE

The present disclosure is proposed to solve these problems and aims to provide an eccentricity measurement system including an eccentricity measurement sensor mounted in a motor and configured to measure all tilt eccentricity, static eccentricity, and dynamic eccentricity of a rotor by using a change in magnetic field generated between the rotor and a stator, thereby overcoming a limitation of a reflective laser sensor method in the related art, reducing costs in comparison with the reflective laser sensor in the related art, detecting an eccentricity factor that most significantly affects noise and vibration of a rotary device, detecting a defect at an initial stage of mass production to prevent shipment of potentially defective products, measuring eccentricity caused by abrasion or the like after product durability testing or after prolonged operation of a vehicle to detect in advance a problem, and taking in advance an action such as repair.

With the above-described eccentricity measurement system, when the eccentricity measurement system is applied to autonomous vehicles in the future, it is possible to monitor a mechanical state of a rotary device, apply the eccentricity measurement system to a smart rotary device system capable of evaluating a state thereof by using a pre-secured defect level index, and recognize the state of the rotary device in a region imperceptible to humans. Furthermore, the eccentricity measurement system may be applied in a case in which it is difficult to recognize a state of an individual rotary device because of external vibration or noise, such that the eccentricity measurement system may be used to detect and address problems in an electric motor used in urban air mobility (UAM) aircraft in advance.

In order to achieve the above-mentioned objects, an embodiment of the present disclosure provides an eccentricity measurement system, which is configured to apply to a motor system including a stator and a rotor and measures an eccentricity of the rotor, the eccentricity measurement system including: an eccentricity measurement part configured to measure a presence or absence of eccentricity of the rotor by measuring a change in magnetic field generated between the rotor and the stator; and a sensing housing comprising: a first surface in which the eccentricity measurement part is embedded, and a center hole through a center of the sensing housing so that a rotary shaft of the rotor is fitted into the center hole, where the first surface faces a distal end of the rotor.

In addition, the eccentricity measurement part may include: a sensing board inserted into the sensing housing; and an eccentricity measurement sensor embedded in the sensing board.

In addition, the sensing housing may include: a ring-shaped center fixing portion having the center hole; and one or more sensor fixing portions protruding radially outward from the center hole and configured such that the eccentricity measurement sensor is embedded in the one or more sensor fixing portions.

In addition, the sensing board may be coupled to correspond to a first sensor fixing portion among the one or more sensor fixing portions in a one-to-one manner, the sensing board is spaced apart from the center fixing portion at a predetermined interval, and the eccentricity measurement sensor may be embedded to correspond to the sensing board in a one-to-one manner.

In addition, the eccentricity measurement part may further include a signal line having a first end electrically connected to the sensing board, and a second end electrically connected to an outside to transmit a sensing signal to the outside, and the first sensor fixing portion may include a signal transmission hole penetrating the first sensor fixing portion so that the signal line passes through the signal transmission hole.

In addition, the sensing board may be coupled to a second surface of the sensing housing, the eccentricity measurement sensor may include a plurality of eccentricity measurement sensors, one or more eccentricity measurement sensors among the plurality of eccentricity measurement sensors may all be embedded in the first surface of the sensing housing, and a region in which a first eccentricity measurement sensor among the plurality of eccentricity measurement sensors is embedded may protrude radially outward so as to correspond to at least one sensor fixing portion among the one or more sensor fixing portions in a one-to-one manner.

In addition, the eccentricity measurement part may further include: an external terminal electrically connected to the eccentricity measurement sensor and configured to transfer sensing information of the eccentricity measurement sensor to an outside; and a circuit pattern on a first surface of the eccentricity measurement part to electrically connect the external terminal and the eccentricity measurement sensor.

In addition, the circuit pattern may include: at least two power supply lines each including two or more power supply terminals configured to supply power to the eccentricity measurement sensor and connected to the eccentricity measurement sensor; and a signal line including two or more signal output terminals configured to output a sensing value of the eccentricity measurement sensor and connected to the eccentricity measurement sensor, each of the power supply lines and the signal line may extend in the same direction, and the two or more power supply terminals and the two or more signal output terminals are spaced apart from one another at predetermined intervals.

In addition, the sensing board may further include a first fixing hole through in a first region excluding a second region in which the circuit pattern is present, the sensing housing may further include a cover on an entirety of the first surface of the sensing housing, and the cover may cover the sensing board, and the cover may include a second fixing hole penetrating the cover at a position corresponding to the first fixing hole.

In addition, at least one sensor fixing portion among the one or more sensor fixing portions may include a housing coupling portion coupled to a motor housing in which the stator and the rotor are accommodated, and the housing coupling portion may include screw holes through the at least one sensor fixing portion and the motor housing.

In addition, at least one sensor fixing portion among the one or more sensor fixing portions may include: a board insertion groove that is recessed so that the sensing board is inserted into the board insertion groove; and an interference avoidance groove that is recessed in a cylindrical shape based on a vertex of the board insertion groove.

In addition, at least one sensor fixing portion among the one or more sensor fixing portions may include a housing coupling portion coupled to a motor housing in which the stator and the rotor are accommodated, and the housing coupling portion may include a fixing stepped portion placed on a coupling structure of a bearing of the motor housing.

In addition, the sensing housing may further include a flat plate-like potting part configured to cover and protect a first surface of the sensing board.

In addition, the eccentricity measurement sensor may include two or more eccentricity measurement sensors, and the eccentricity measurement sensors may be disposed to be spaced apart from one another at equal intervals.

In addition, the eccentricity measurement sensor may include two or more eccentricity measurement sensors, and the eccentricity measurement sensors may be disposed to be spaced apart from one another with a phase difference of 90 degrees.

### BRIEF DESCRIPTION OF THE DRAWINGS

FIG. 1 is an axial cross-sectional view illustrating a motor system to which an eccentricity measurement system of the present disclosure.

FIG. 2 is a top plan view illustrating an eccentricity measurement system according to a first embodiment of the present disclosure.

FIG. 3 is a schematic view illustrating an eccentricity measurement part of the first embodiment of the present disclosure.

FIG. 4 is an axial cross-sectional view illustrating a sensing housing of the first embodiment of the present disclosure.

FIG. 5 is a top plan view illustrating an eccentricity measurement system according to a second embodiment of the present disclosure.

FIG. 6 is a schematic view illustrating a circuit pattern according to the second embodiment of the present disclosure.

FIG. 7 is a schematic view illustrating a detailed embodiment of the circuit pattern according to the second embodiment of the present disclosure.

FIG. 8 is a top plan view illustrating a sensing board having first fixing holes of the second embodiment of the present disclosure.

FIG. 9 is a perspective view illustrating a sensing housing to which a cover of the second embodiment of the present disclosure is coupled.

FIG. 10 is a perspective view illustrating the sensing housing of the present disclosure.

FIG. 11 is a top plan view illustrating the sensing housing of the present disclosure.

FIG. 12 is an axial cross-sectional view illustrating the sensing housing of the present disclosure.

FIG. 13 is a perspective view illustrating the sensing housing to which a potting part of the present disclosure is coupled.

FIGS. 14 to 16 are schematic views illustrating embodiments of an arrangement of an eccentricity measurement sensor of the present disclosure.

FIGS. 17 and 18 are schematic views illustrating a positional relationship between a rotor and the eccentricity measurement sensor in the event of tilt eccentricity.

FIG. 19 is a schematic view illustrating a positional relationship between the rotor and the eccentricity measurement sensor in the event of static eccentricity.

FIG. 20 is a schematic view illustrating a positional relationship between the rotor and the eccentricity measurement sensor in the event of dynamic eccentricity.

FIGS. 21 to 22 are schematic views illustrating graphs of magnetic flux amounts measured by two eccentricity measurement sensors in the event of tilt eccentricity.

FIG. 23 is a schematic view illustrating graphs of the magnetic flux amounts measured by the two eccentricity measurement sensors in the event of static eccentricity.

FIG. 24 is a schematic view illustrating graphs of the magnetic flux amounts measured by the two eccentricity measurement sensors in the event of dynamic eccentricity.

### DETAILED DESCRIPTION OF THE DISCLOSURE

Hereinafter, the technical spirit of the present disclosure will be described in more detail using the accompanying drawings. In addition, terms or words used in the specification and the claims should not be interpreted as being limited to a general or dictionary meaning and should be interpreted as a meaning and a concept which conform to the technical spirit of the present disclosure based on a principle that an inventor can appropriately define a concept of a term in order to describe his/her own invention by the best method.

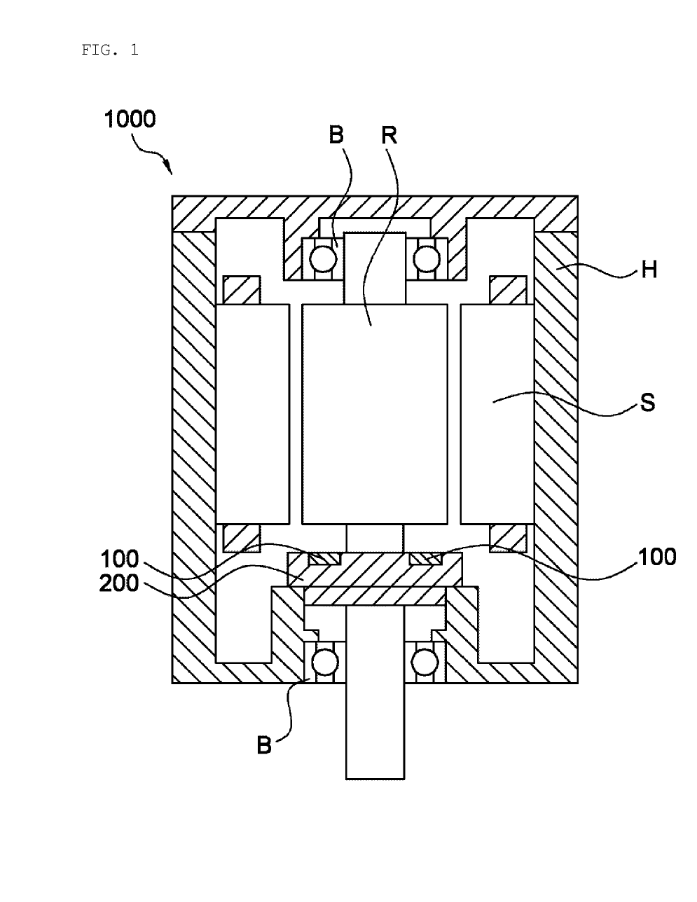

Hereinafter, a basic configuration of an eccentricity measurement system 1000 of the present disclosure will be described with reference to FIG. 1.

As illustrated in FIG. 1, the eccentricity measurement system 1000 of the present disclosure may be applied to a motor system including a stator S and a rotor R and measure eccentricity of the rotor R. The eccentricity measurement system 1000 may include eccentricity measurement parts 100 and a sensing housing 200. The eccentricity measurement part 100 may be provided to face an axially distal end surface of the rotor R and measure the presence or absence of the eccentricity of the rotor R by using a change in magnetic field generated between the rotor R and the stator S. The eccentricity measurement part 100 may include a Hall sensor that is a magnetic flux density sensor. Therefore, it is possible to output an analog signal with a waveform to the outside in order to analyze a signal waveform of the eccentricity of the rotor R, and the eccentricity of the rotor R may be recognized by analyzing sensing information by an external controller based on the analog signal. In addition, a center hole 210, into which a rotary shaft of the rotor R is fitted, is formed through a center of the sensing housing 200. One surface (e.g., first surface) of the sensing housing 200 may be provided to face the distal end of the rotor R, and the eccentricity measurement part 100 may be embedded in one surface of the sensing housing 200 that faces the distal end of the rotor R.

The eccentricity measurement part 100, which measures the eccentricity, and the sensing housing 200, which supports the eccentricity measurement part 100, may be provided at the axially distal end of the rotor R, as described above, thereby measuring all tilt eccentricity, static eccentricity, and dynamic eccentricity of the rotor R, reducing costs in comparison with a reflective laser sensor in the related art, detecting an eccentricity factor that most significantly affects noise and vibration of a rotary device, and detecting a defect at an initial stage of mass production.

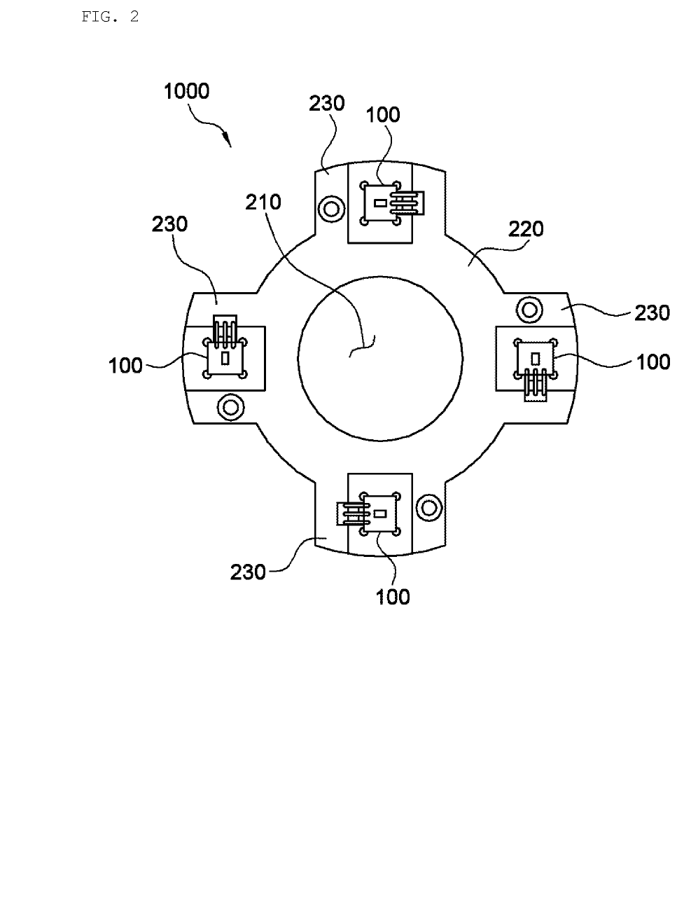

Hereinafter, a first embodiment of the present disclosure will be described in more detail with reference to FIGS. 2 to 4.

As illustrated in FIG. 2, the eccentricity measurement part 100 may include a sensing board 110 inserted into the sensing housing 200, and an eccentricity measurement sensor 120 embedded in the sensing board 110. In addition, the sensing housing 200 may include a ring-shaped center fixing portion 220 having the center hole 210, and one or more sensor fixing portions 230 protruding radially outward from the center hole 210 and configured such that the sensing boards 110 and the eccentricity measurement sensors 120 are embedded in the sensor fixing portions 230. In addition, the sensing housing 200 may be a non-conductive plastic injection-molded product. Therefore, a motor housing H, which is made of a metallic material, may be electrically insulated from the sensing board 110 of the eccentricity measurement part 100.

In this case, in the first embodiment of the eccentricity measurement system 1000 of the present disclosure, the sensor fixing portions 230 may be provided as one or more sensor fixing portions 230, and the sensing boards 110 of the eccentricity measurement parts 100 may be provided separately for the respective eccentricity measurement sensors 120. More specifically, the sensing board 110 may be coupled to correspond to the sensor fixing portion 230 in a one-to-one manner and spaced apart from the center fixing portion 220 at a predetermined interval. That is, the sensing board 110 and the eccentricity measurement sensor 120 may be fixed to correspond to the sensor fixing portion 230 in a one-to-one manner. In addition, the sensor fixing portions 230 may protrude by the same length so that the intervals between the eccentricity measurement sensors 120 and the center hole 210 are constant. Therefore, when the eccentricity occurs in the rotor R, signal values measured by the respective eccentricity measurement sensors may become different from one another, and the type of eccentricity of the rotor R and a direction in which the rotor R is eccentric may be more smoothly recognized.

In addition, the number of applied eccentricity measurement sensors 120 may be applied within the number that prevents the saturation of the Hall sensor because of a large magnetic flux amount of the rotor R under an operation condition of a motor to which the eccentricity measurement system 1000 of the present disclosure is applied. In addition, this may be controlled by adjusting a coupling position of the sensing housing 200, i.e., an axial spacing distance between the eccentricity measurement part 100, the sensing housing 200, and the rotor R. In addition, the eccentricity measurement sensor 120 may be a surface-mount type eccentricity measurement sensor coupled to one surface (e.g., first surface) of the sensing board 110. In addition, because the eccentricity measurement sensor 120 is coupled to a surface of the sensing board 110, the type and specification of the eccentricity measurement sensor 120 may be easily changed in accordance with a usage environment (temperature or the like) of the motor, such that it is possible to gain advantages in terms of repair and manufacturing costs.

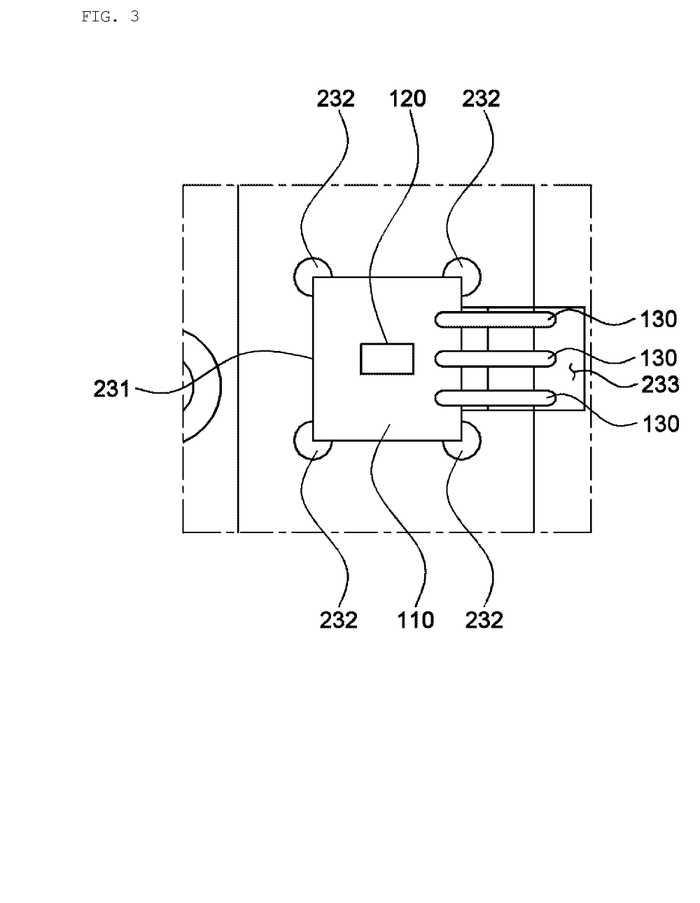

In addition, as illustrated in FIG. 3, the eccentricity measurement part 100 may include signal lines 130 each having one end (e.g., a first end) electrically connected to the sensing board 110, and the other end (e.g., a second end) electrically connected to the outside to transmit a sensing signal to the outside. The signal line 130 may penetrate the sensing housing 200 and be electrically connected to an external controller. Therefore, the external controller may analyze a magnetic field signal generated from the eccentricity measurement sensor 120 that is a Hall sensor. Further, the presence or absence of eccentricity in the rotor R may be identified.

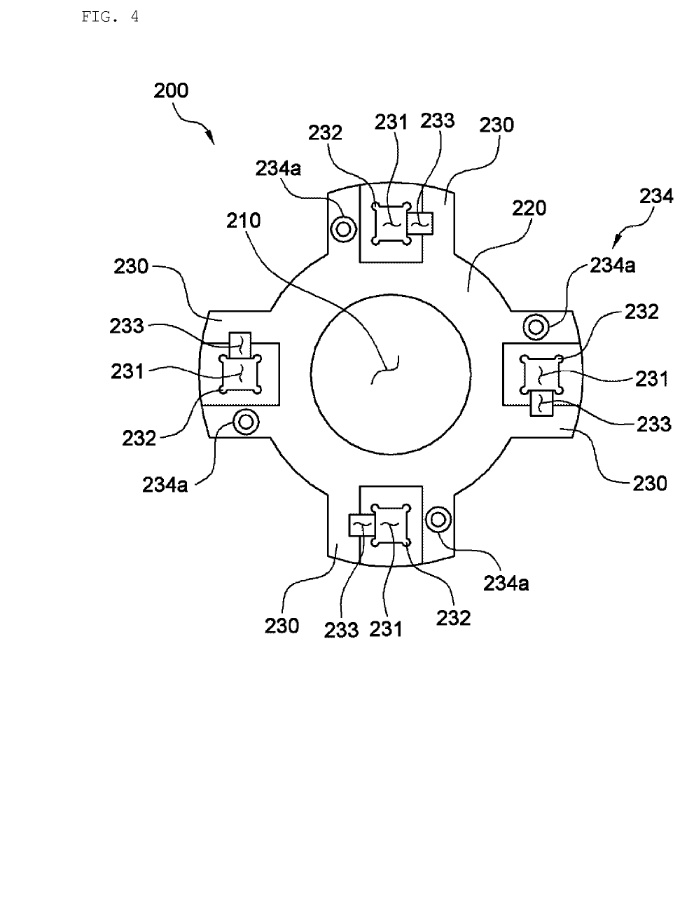

In addition, as illustrated in FIG. 4, the sensor fixing portion 230 may include a signal transmission hole 233 penetratively formed so that the signal lines 130 pass through the signal transmission hole 233. Because the signal transmission hole 233 is included, the signal lines 130 of the eccentricity measurement part 100 may be connected to the external controller provided outside the sensing housing 200, and a measurement value of the eccentricity measurement sensor 120 may be outputted to the external controller.

As described above, with the application of the first embodiment of the present disclosure, the eccentricity measurement sensors 120 may each be mounted on each of the small sensing boards 110, thereby improving the convenience in using the eccentricity measurement sensors 120 in various motors in common. That is, a shape of the sensing housing 200 may not be limited as long as a shape of a holder for assembling the eccentricity measurement part 100 is present.

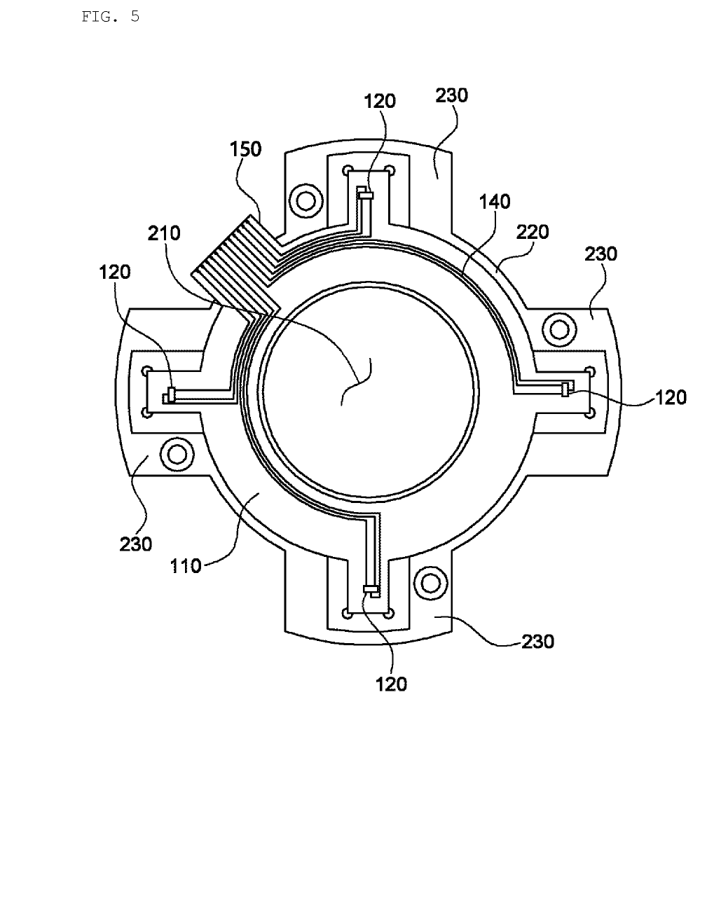

Hereinafter, a second embodiment of the present disclosure will be described in more detail with reference to FIGS. 5 to 9.

As illustrated in FIG. 5, the eccentricity measurement part 100 may include the sensing board 110 inserted into the sensing housing 200, and the eccentricity measurement sensors 120 embedded in the sensing board 110. In addition, the sensing housing 200 may include the ring-shaped center fixing portion 220 having the center hole 210, and one or more sensor fixing portions 230 protruding radially outward from the center hole 210 and configured such that the sensing board 110 and the eccentricity measurement sensors 120 are embedded in the sensor fixing portions 230. In addition, the sensing housing 200 may be a non-conductive plastic injection-molded product. Therefore, the motor housing H, which is made of a metallic material, may be electrically insulated from the sensing board 110 of the eccentricity measurement part 100.

In this case, in the second embodiment of the eccentricity measurement system 1000 of the present disclosure, the sensing board 110 may be coupled to one front surface (e.g., second surface) of the sensing housing 200, and one or more eccentricity measurement sensors 120 may all be embedded in one surface of the sensing board 110. In this case, in the sensing board 110, regions, in which the eccentricity measurement sensors 120 are embedded, may protrude radially outward so as to correspond to the plurality of sensor fixing portions 230.

In addition, the number of applied eccentricity measurement sensors 120 may be applied within the number that prevents the saturation of the Hall sensor because of a large magnetic flux amount of the rotor R under an operation condition of a motor to which the eccentricity measurement system 1000 of the present disclosure is applied. In addition, this may be controlled by adjusting a coupling position of the sensing housing 200, i.e., an axial spacing distance between the eccentricity measurement part 100, the sensing housing 200, and the rotor R. In addition, the eccentricity measurement sensor 120 may be a surface-mount type eccentricity measurement sensor coupled to one surface of the sensing board 110. In addition, because the eccentricity measurement sensor 120 is coupled to a surface of the sensing board 110, the type and specification of the eccentricity measurement sensor 120 may be easily changed in accordance with a usage environment (temperature or the like) of the motor, such that it is possible to gain advantages in terms of repair and manufacturing costs.

As described above, because the plurality of eccentricity measurement sensors 120 are coupled to one sensing board 110, the plurality of eccentricity measurement sensors 120 may be integrally detached from the sensing housing 200. Therefore, the sensing housing 200, which may be inserted into one sensing board 110, may be used in common for various types of motors, thereby improving convenience. That is, a shape of the sensing housing 200 may not be limited as long as a shape of a holder for assembling the eccentricity measurement part 100 is present.

In addition, in the second embodiment of the present disclosure, the eccentricity measurement part 100 may further include an external terminal 150 electrically connected to the eccentricity measurement sensor 120 and configured to transfer sensing information of the eccentricity measurement sensor 120 to the outside, and a circuit pattern 140 printed on one surface (e.g., first surface) of the eccentricity measurement part 100 to electrically connect the external terminal 150 and the eccentricity measurement sensor 120. A connector electrically connected to the external controller may be inserted into the external terminal 150 so that the external controller, the circuit pattern 140, and the eccentricity measurement sensor 120 are electrically connected.

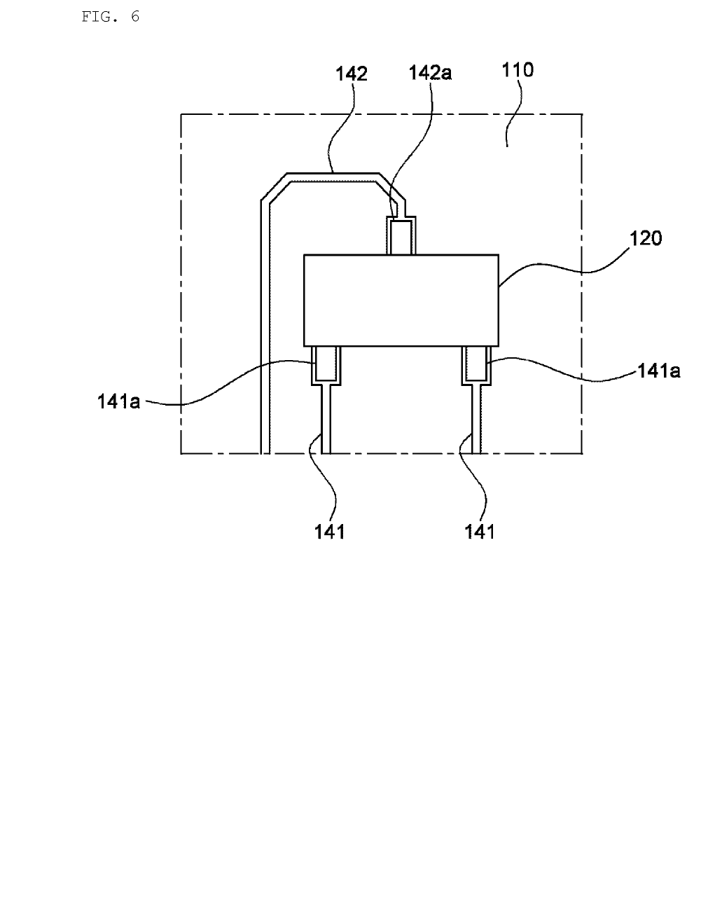

In addition, as illustrated in FIG. 6, the circuit pattern 140 may include power supply lines 141 and a signal line 142. The power supply lines 141 may include power supply terminals 141a configured to supply power to the eccentricity measurement sensor 120 and connected to the eccentricity measurement sensor 120. The power supply lines 141 may be printed as two + and – lines on each of the eccentricity measurement sensors 120. At least one power supply terminal 141a may be provided on each of the power supply lines 141. In addition, the signal line 142 may include signal output terminals 142a configured to output a sensing value of the eccentricity measurement sensor 120 and connected to the eccentricity measurement sensor 120. One signal line 142 may be printed on each of the eccentricity measurement sensors 120.

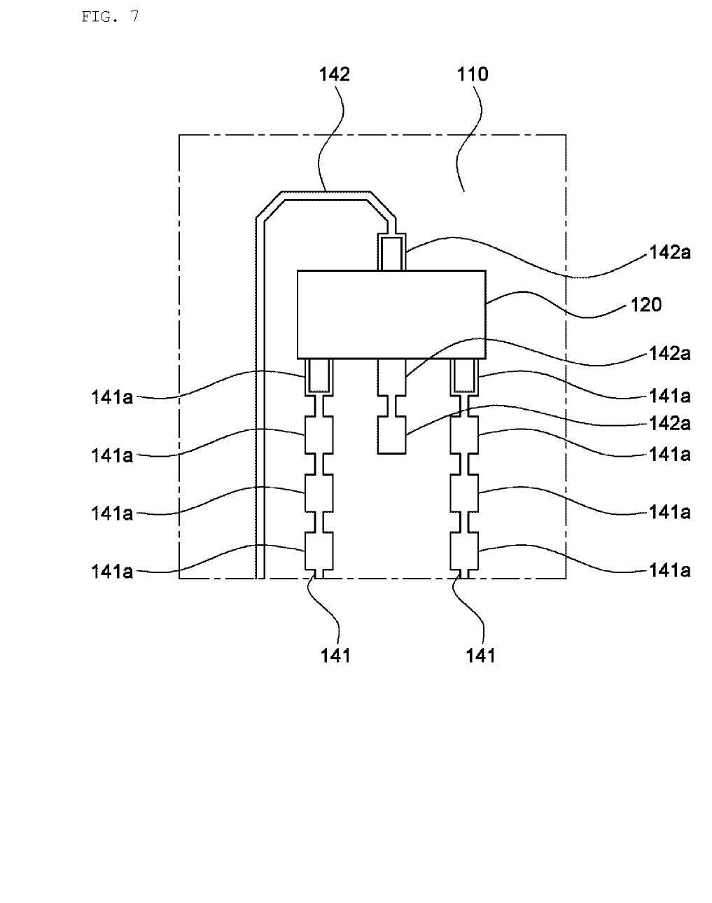

In addition, in a detailed embodiment of the second embodiment of the present disclosure, as illustrated in FIG. 7, the power supply line 141 and the signal line 142 may be formed to extend in the same direction. For example, the power supply line 141 and the signal line 142 may extend in a radial direction in a region corresponding to the sensor fixing portion 230. In addition, the power supply terminals 141a and the signal output terminals 142a may be provided as two or more power supply terminals and two or more signal output terminals respectively provided on the power supply line 141 and the signal line 142 and spaced apart from one another at predetermined intervals. More specifically, the power supply terminals 141a and the signal output terminals 142a may be provided to be spaced apart from one another at predetermined intervals in the radial direction that is the extension direction of the power supply line 141 and the signal line 142.

Therefore, a plurality of pairs of terminals each including two power supply terminals 141a and one signal output terminal 142a to which the eccentricity measurement sensor 120 may be coupled may be provided in the radial direction. Therefore, the position to which the eccentricity measurement sensor 120 is coupled may be easily changed. That is, the radial position to which the eccentricity measurement sensor 120 is coupled may be easily changed, such that the eccentricity measurement system 1000 may be easily applied even though a target radial position of the eccentricity measurement sensor 120 varies depending on a change in type of motor.

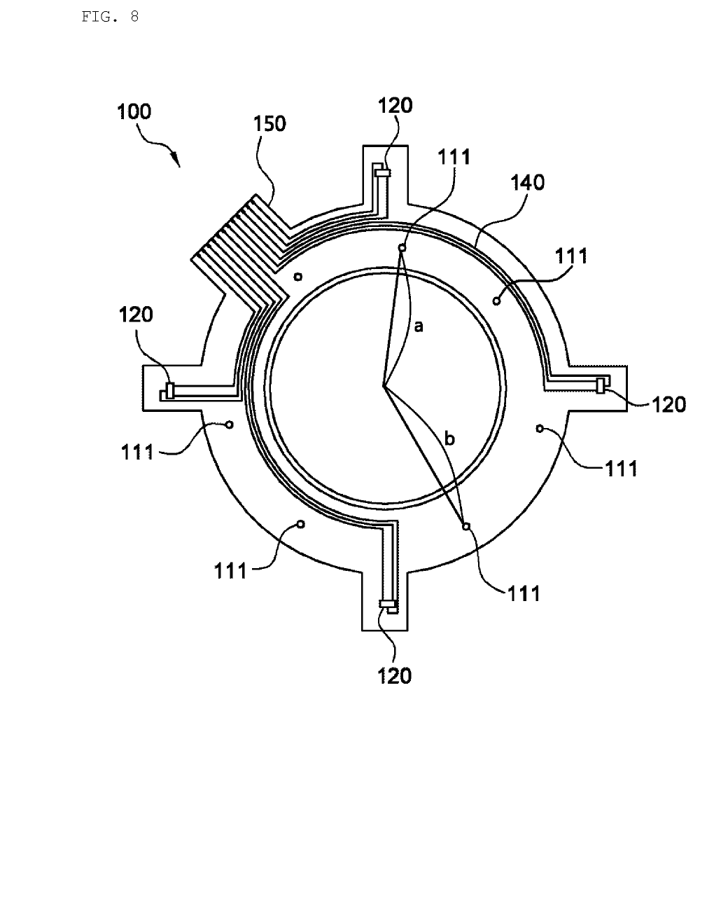

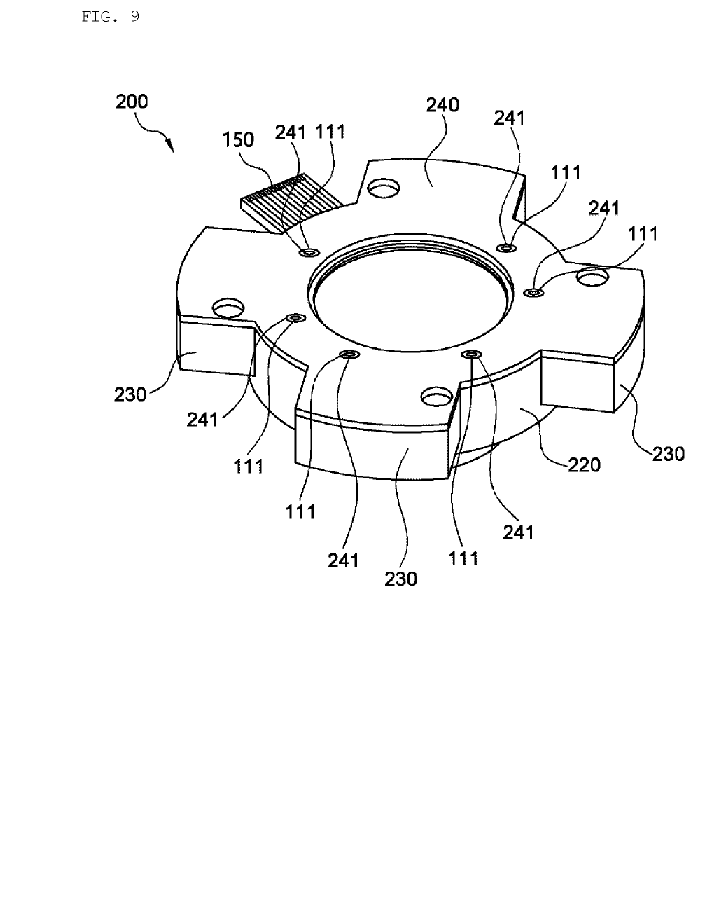

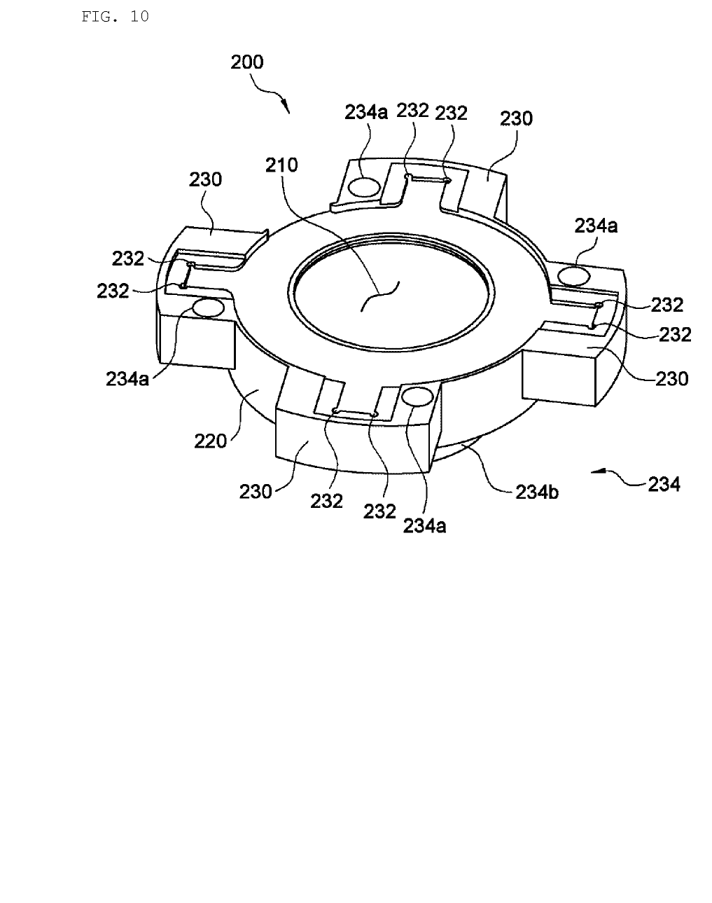

In addition, as illustrated in FIG. 8, the sensing board 110 may further include first fixing holes 111 penetratively formed in a region (e.g., first region) excluding the region (e.g., second region) in which the circuit pattern 140 is formed. Because the first fixing holes 111 may be formed to avoid the circuit pattern 140 without affecting the electrical connection between the eccentricity measurement sensors 120, the external terminal 150, and the external controller. To this end, the first fixing holes 111 may be formed to be different in distances from the center. That is, a and b in FIG. 10 may be different from each other. In addition, as illustrated in FIG. 9, the sensing housing 200 may include a cover 240 provided on the entirety of one surface and configured to cover the sensing board 110, and the cover 240 may include second fixing holes 241 penetratively formed at positions corresponding to the first fixing holes 111. In this case, fasteners may be inserted into the first fixing holes 111 and the second fixing holes 241, and the positions of the first fixing holes 111 and the positions of the second fixing holes 241 may be fixed. Because the cover 240 is included, the eccentricity measurement system 1000 of the present disclosure may be used even in a harsh environment, thereby improving the utilization of the eccentricity measurement system 1000.

Hereinafter, the sensing housing 200 of the present disclosure will be described in detail with reference to FIGS. 10 to 13.

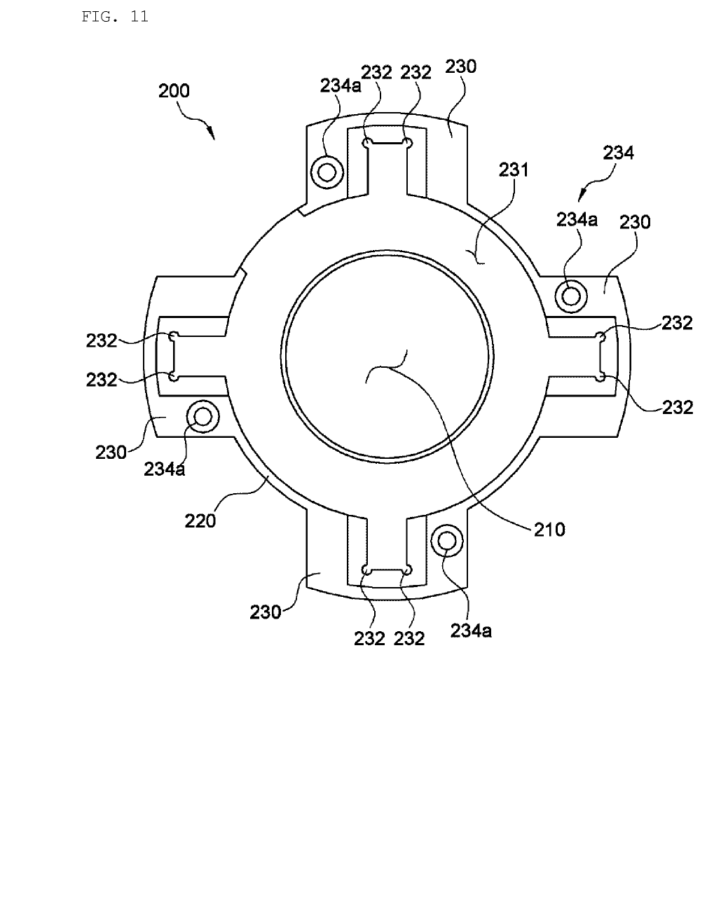

As illustrated in FIG. 11, in this case, the sensor fixing portions 230 may each include a board insertion groove 231 concavely formed so that the sensing board 110 is inserted into the board insertion groove 231, and interference avoidance grooves 232 concavely formed in cylindrical shapes based on vertices of the board insertion groove 231. The board insertion groove 231 may be formed to have the same thickness as the sensing board 110 or formed to be deeper than the sensing board 110. In addition, the interference avoidance grooves 232 may be formed at the respective vertices of the board insertion groove 231. Because the board insertion groove 231 is included, the sensing board 110 may be completely inserted into the sensing housing 200 without protruding from an outer surface of the sensing housing 200. In addition, because the interference avoidance grooves 232 are included, the sensing board 110 may be more easily inserted into the board insertion groove 231.

In addition, as illustrated in FIG. 11, the sensor fixing portion 230 may include housing coupling portions 234 coupled to the motor housing H in which the stator S and the rotor R are accommodated. The housing coupling portion 234 may include screw holes 234a formed through the sensor fixing portions 230 and the motor housing H. Fasteners may be inserted into the screw holes 234a. The fastener inserted into the screw hole 234a may penetrate the sensing housing 200 and be inserted into the motor housing H. At least one screw hole 234a may be formed in each of the sensor fixing portions 230 protruding radially outward. Therefore, the positions of the sensor fixing portions 230 to which the eccentricity measurement sensors 120 are applied may be maintained constantly, thereby further improving the accuracy in measuring the eccentricity.

FIGS. 10 to 11 illustrate the sensing housing 200 of the second embodiment of the present disclosure. All the board insertion groove 231, the interference avoidance groove 232, the housing coupling portion 234, and the components disposed therebelow may also be applied to the first embodiment of the present disclosure (see FIG. 4).

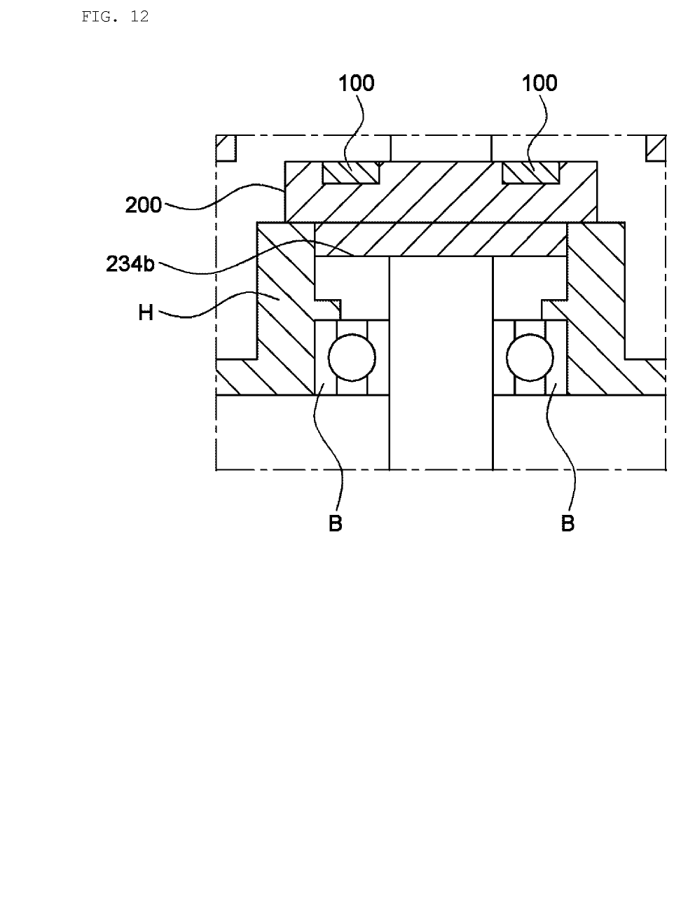

In addition, as illustrated in FIG. 12, the housing coupling portion 234 may include a fixing stepped portion 234b placed on a coupling structure of a bearing B of the motor housing H. Because the fixing stepped portion 234b is included, an axial position of the sensing housing 200 may be fixed. A radial position of the sensing housing 200 may be maintained by the above-mentioned center hole 210. Therefore, even though the motor rotates at a high speed, the position of the sensing housing 200 may be more stably fixed, thereby further improving the accuracy in measuring the eccentricity.

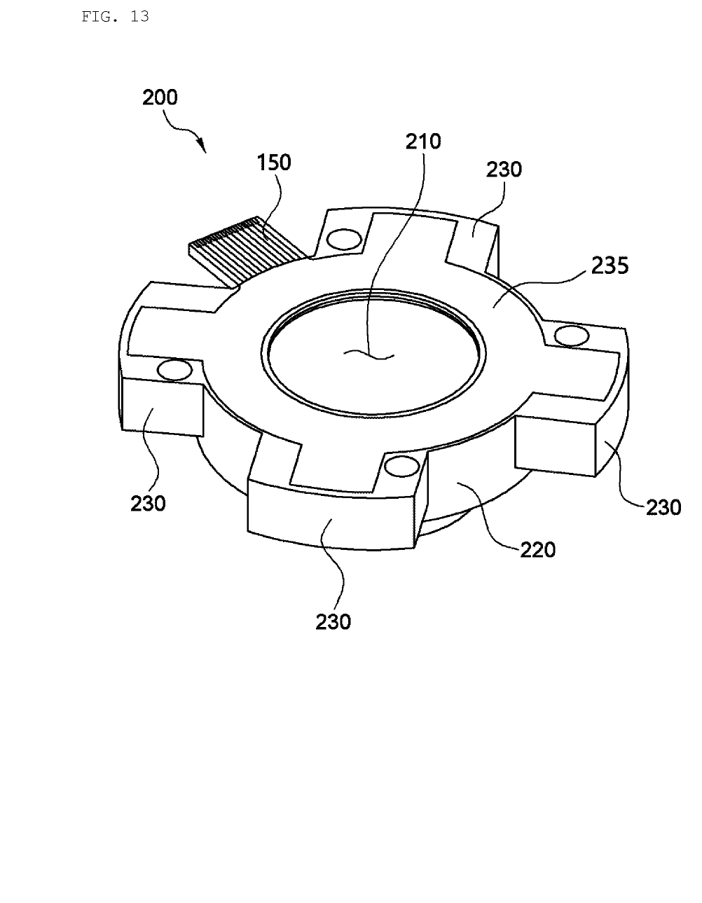

In addition, as illustrated in FIG. 13, the sensing housing 200 may further include a flat plate-like potting part 235 configured to cover and protect one surface of the sensing board 110. The potting part 235 may be made of epoxy or silicone.

In this case, a depth of the board insertion groove 231 may be larger than a sum of a height of the sensing board 110 and a height of the eccentricity measurement sensor 120. Thereafter, the potting part 235 may be added to the board insertion groove 231, thereby protecting the eccentricity measurement part 100 from an external environment. Because the potting part 235 is included, the eccentricity measurement system 1000 of the present disclosure may be used even in a harsh environment, thereby improving the utilization of the eccentricity measurement system 1000.

In addition, for example, the eccentricity measurement part 100 is inserted in advance into a mold for performing injection-molding on the sensing housing 200, and the eccentricity measurement part 100 may be manufactured together with the sensing housing 200 by insert-injection molding. In this case, a material, which may be injected at a low temperature, may be applied to the sensing housing 200 in consideration of heat resistance of the eccentricity measurement part 100. For example, bulk molding compound (BMC) may be applied as a material of the sensing housing 200. With the application of the above-mentioned configuration, the eccentricity measurement system 1000 of the present disclosure may be used even in a harsh environment, thereby improving the utilization of the eccentricity measurement system 1000.

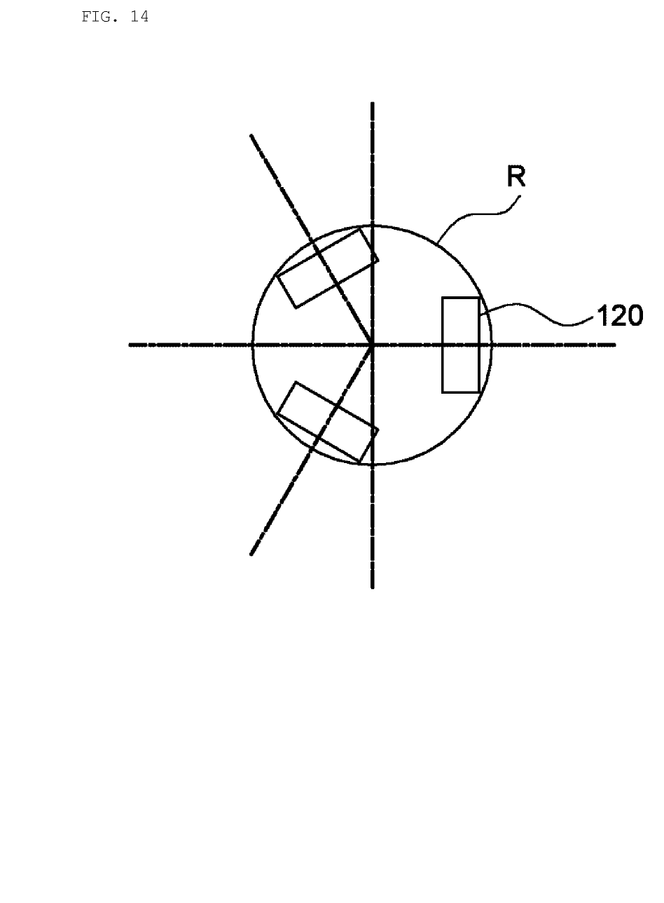

Hereinafter, embodiments of an arrangement of the eccentricity measurement sensor 120 of the present disclosure will be described in more detail with reference to FIGS. 14 to 16.

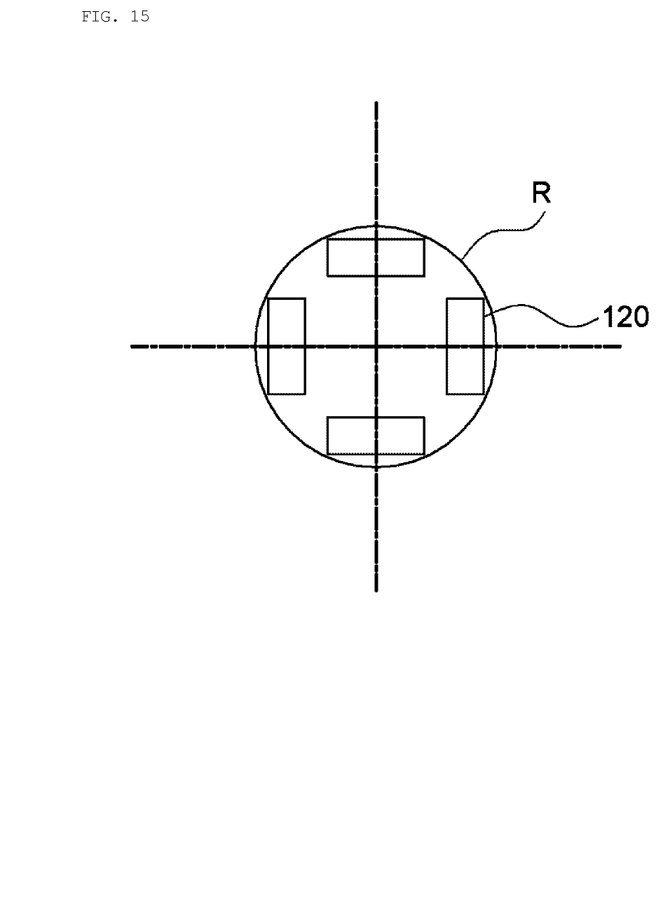

As illustrated in FIGS. 14 and 15, two or more eccentricity measurement parts 100 may be disposed in the sensing housing 200, one eccentricity measurement part 100 may be embedded in each of the sensor fixing portions 230, and the eccentricity measurement sensors 120 embedded in the eccentricity measurement parts 100 may be disposed to be spaced apart from one another at equal intervals. Because two or more eccentricity measurement sensors 120 are applied, the eccentric state may be identified by comparing data between the sensors in case that it is difficult to identify reference data when no eccentricity is present. In more detail, as illustrated in FIG. 14, in case that three eccentricity measurement sensors 120 are applied, the eccentricity measurement sensors 120 may be positioned at positions with a phase difference of 120 degrees based on the stator S and a rotation axis of the rotor R. Alternatively, as illustrated in FIG. 15, in case that four eccentricity measurement sensors 120 are applied, the eccentricity measurement sensors 120 may be positioned at positions with a phase difference of 90 degrees based on the stator S and the rotation axis of the rotor R. Likewise, in case that two eccentricity measurement sensors 120 are applied, the eccentricity measurement sensors 120 may be positioned at positions with a phase difference of 180 degrees based on the stator S and the rotation axis of the rotor R.

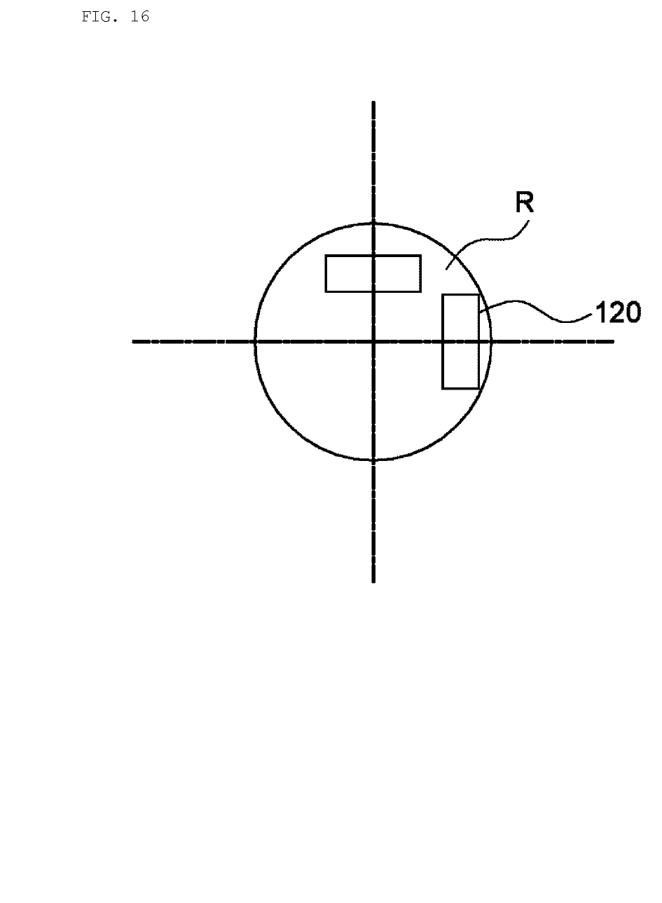

In addition, as illustrated in FIG. 16, two or more eccentricity measurement parts 100 may be disposed in the sensing housing 200, one eccentricity measurement part 100 may be embedded in each of the sensor fixing portions 230, and the eccentricity measurement sensors 120 embedded in the eccentricity measurement parts 100 may be disposed to be spaced apart from one another while having a phase difference of 90 degrees. Therefore, the eccentric state may be identified by comparing data between the sensors in case that it is difficult to identify the reference data when no eccentricity is present.

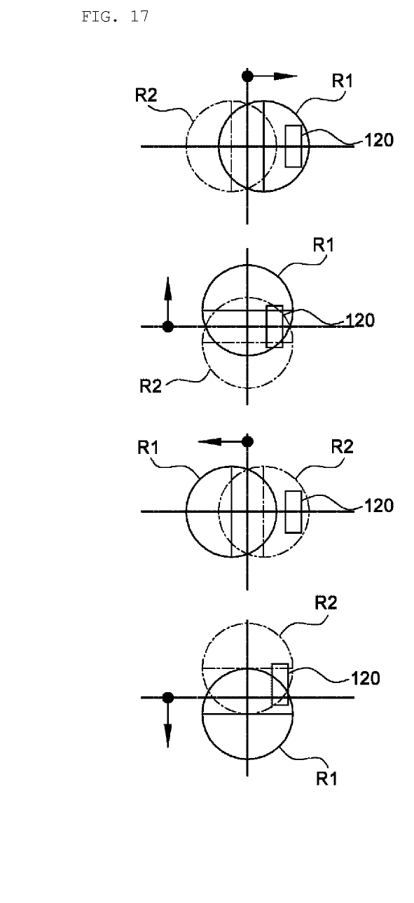

Hereinafter, an algorithm for measuring the eccentricity of the rotor R by using the eccentricity measurement sensor 120 of the present disclosure will be described with reference to FIGS. 17 to 24.

As illustrated in FIG. 17, in case that one eccentricity measurement sensor 120 is applied and an upper end R1 and a lower end R2 of the rotor are inclined to the same degree in opposite (radial) directions (tilt eccentricity case 1), the magnetic flux amount at the side close to the eccentricity measurement sensor 120 may increase, and the magnetic flux amount at the side distant from the eccentricity measurement sensor 120 may decrease. That is, the overall magnetic flux amount may change.

In more detail, in case that eccentricity occurs in a leftward/rightward direction in FIG. 17, an aspect may be measured in which the magnetic flux amount only at any one of the upper end R1 or the lower end R2 of the rotor R increases, and the magnetic flux amount at the other of the upper end R1 or the lower end R2 of the rotor R decreases. That is, it can be ascertained that in case that the magnetic flux amount at the upper end R1 of the rotor increases and the magnetic flux amount at the lower end R2 of the rotor decreases, the upper end R1 of the rotor is inclined toward the eccentricity measurement sensor 120. In the opposite case, it can be ascertained that the lower end R2 of the rotor is inclined toward the eccentricity measurement sensor 120.

In addition, in case that eccentricity occurs in an upward/downward direction in FIG. 17, both the upper end R1 and the lower end R2 of the rotor R are distant from the eccentricity measurement sensor 120, such that the magnetic flux amounts may decrease at both the upper end R1 and the lower end R2 of the rotor R. Therefore, it can be ascertained that the eccentricity occurs in a direction perpendicular to the direction in which the rotor R faces the eccentricity measurement sensor 120.

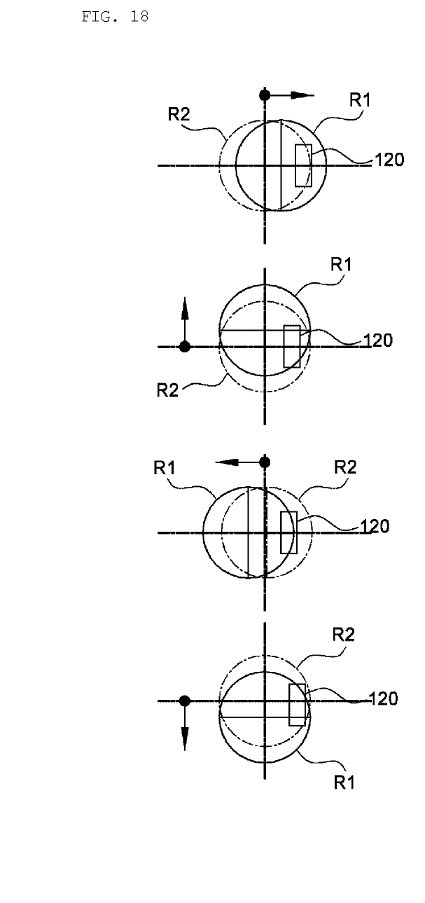

As illustrated in FIG. 18, in case that one eccentricity measurement sensor 120 is applied and only any one of the upper end R1 and the lower end R2 of the rotor R is inclined (tilt eccentricity case 2), the inclined side of the rotor R becomes close to or distant from the eccentricity measurement sensor 120, such that the magnetic flux amount may increase or decrease.

In more detail, in case that eccentricity occurs, an aspect may be measured in which the magnetic flux amount only at any one of the upper end R1 or the lower end R2 of the rotor R increases or decrease, and the magnetic flux amount at the other of the upper end R1 or the lower end R2 of the rotor R is maintained. That is, it can be ascertained that in case that the magnetic flux amount at the upper end R1 of the rotor increases or decreases and the magnetic flux amount at the lower end R2 of the rotor is maintained, the upper end R1 of the rotor is inclined. In the opposite case, it can be ascertained that the lower end R2 of the rotor is inclined.

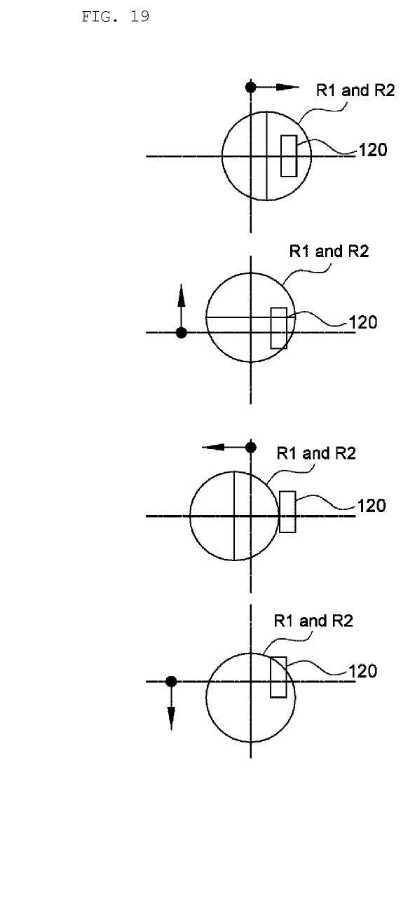

As illustrated in FIG. 19, in case that one eccentricity measurement sensor 120 is applied and both the upper end R1 and the lower end R2 of the rotor R are constantly eccentric, i.e., in case that the rotor R is eccentric in the radial direction (static eccentricity), both the upper end R1 and the lower end R2 of the rotor R become close to or distant from the eccentricity measurement sensor 120 in the same way, such that the magnetic flux amount may increase or decrease. That is, it can be ascertained that the rotor R is statically eccentric toward the eccentricity measurement sensor 120 when the magnetic flux amounts at the upper end R1 and the lower end R2 of the rotor simultaneously increase in the same way, and the rotor R is statically eccentric in a direction away from the eccentricity measurement sensor 120 when the magnetic flux amounts at the upper end R1 and the lower end R2 of the rotor simultaneously decrease in the same way.

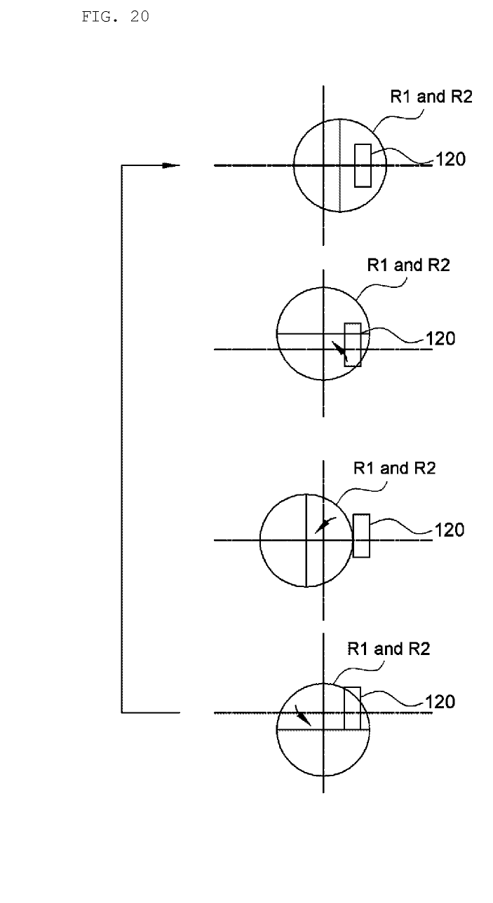

In addition, as illustrated in FIG. 20, in case that one eccentricity measurement sensor 120 is applied and a value of an air gap changes over time (dynamic eccentricity), the magnetic flux amount measured from the rotor R may change over time, and the cycle of the magnetic flux amount may also change. In more detail, when the rotor R becomes close to the eccentricity measurement sensor 120, the magnetic flux amount may increase at the same time when the cycle of the magnetic flux amount is shortened. When the rotor R becomes distant from the eccentricity measurement sensor 120 in the opposite direction, the magnetic flux amount may decrease at the same time when the cycle of the magnetic flux amount is lengthened.

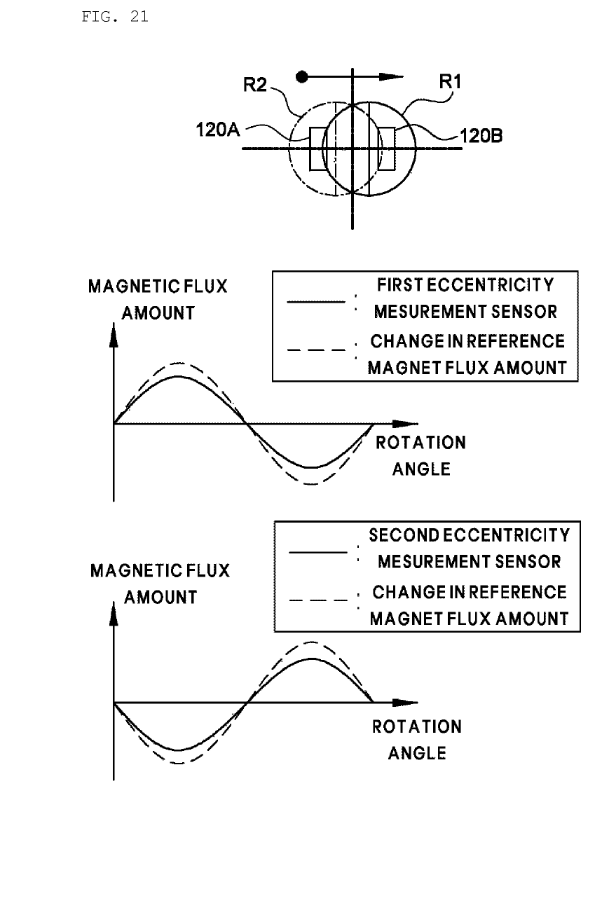

In addition, as illustrated in FIG. 21, in case that two eccentricity measurement sensors 120 are applied and the upper and lower sides of the rotor R are inclined to the same degree in opposite (radial) directions (tilt eccentricity case 1), the magnetic flux amount close at the side to the eccentricity measurement sensor 120 may increase, and the magnetic flux amount at the side distant from the eccentricity measurement sensor 120 may decrease. That is, the overall magnetic flux amount may change.

For example, in case that a first eccentricity measurement sensor 120A and a second eccentricity measurement sensor 120B are disposed to be spaced apart from each other with a phase difference of 180 degrees and the tilt eccentricity of the rotor R occurs at the first eccentricity measurement sensor 120A and the second eccentricity measurement sensor 120B, the magnetic flux amount may partially decrease in comparison with a reference magnetic flux amount determined when no eccentricity occurs at both the first eccentricity measurement sensor 120A and the second eccentricity measurement sensor 120B. This represents an aspect in which the magnetic flux amount decreases as the upper end R1 or the lower end R2 of the rotor R becomes distant from the first eccentricity measurement sensor 120A and the second eccentricity measurement sensor 120B.

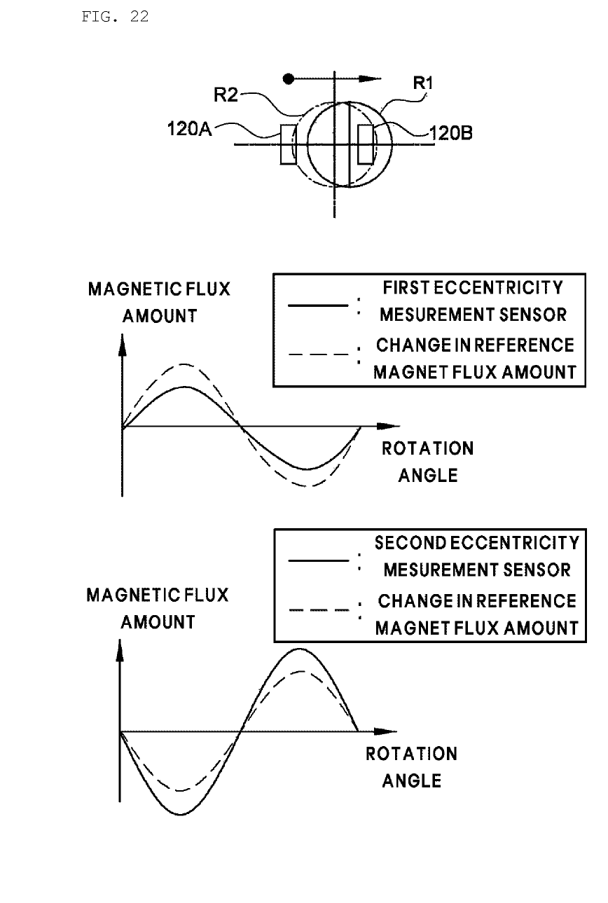

In addition, as illustrated in FIG. 22, in case that two eccentricity measurement sensors 120 are applied and only any one of the upper end R1 and the lower end R2 of the rotor R is inclined (tilt eccentricity case 2), the magnetic flux amount at the side close to the eccentricity measurement sensor 120 may increase, the magnetic flux amount at the side distant from the eccentricity measurement sensor 120 may decrease, and the magnetic flux amount at another side may be maintained. For example, in case that the first eccentricity measurement sensor 120A and the second eccentricity measurement sensor 120B are disposed to be spaced apart from each other with a phase difference of 180 degrees and the eccentricity of the upper end R1 of the rotor occurs so that the upper end R1 of the rotor becomes close to the second eccentricity measurement sensor 120B, the magnetic flux amount at the first eccentricity measurement sensor 120A may become partially smaller than a reference value, and the magnetic flux amount at the second eccentricity measurement sensor 120B may become partially larger than the reference value.

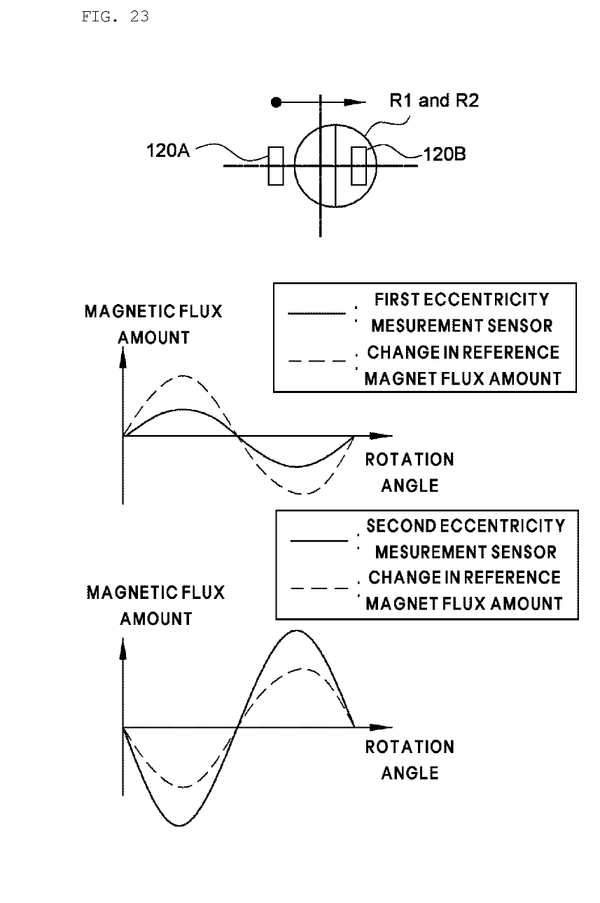

In addition, as illustrated in FIG. 23, in case that two eccentricity measurement sensors 120 are applied and both the upper end R1 and the lower end R2 of the rotor R are constantly eccentric, i.e., in case that the rotor R is eccentric in the radial direction (static eccentricity), both the upper end R1 and the lower end R2 of the rotor R become close to or distant from the eccentricity measurement sensor 120 in the same way, such that the magnetic flux amount may increase or decrease. That is, the magnetic flux amounts at the upper end R1 and the lower end R2 of the rotor may simultaneously increase in the same way. For example, in case that the first eccentricity measurement sensor 120A and the second eccentricity measurement sensor 120B are disposed to be spaced apart from each other with a phase difference of 180 degrees and the eccentricity of the rotor occurs so that the rotor becomes close to the second eccentricity measurement sensor 120B, the magnetic flux amount at the first eccentricity measurement sensor 120A may become significantly smaller than a reference value, and the magnetic flux amount at the second eccentricity measurement sensor 120B may become significantly larger than the reference value.

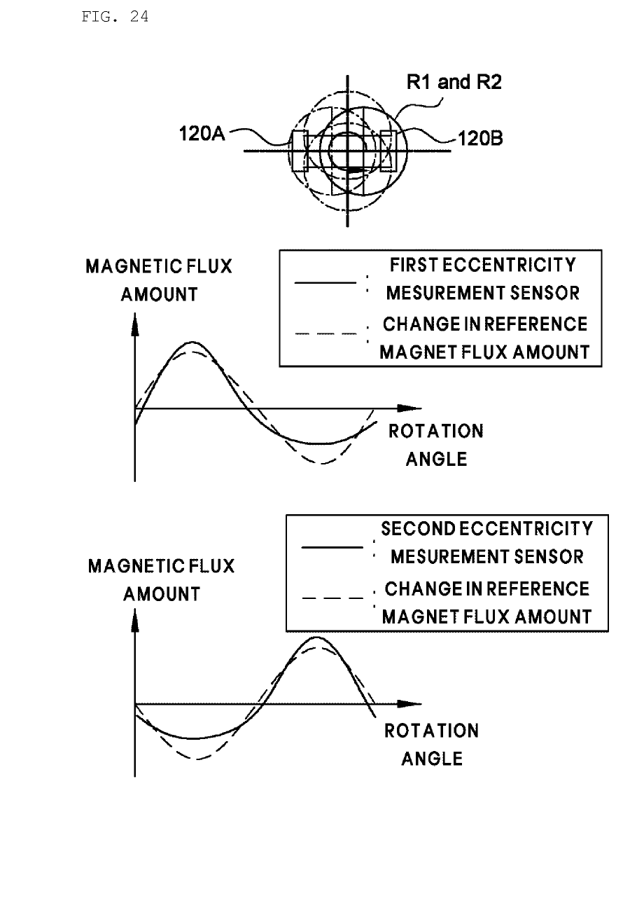

In addition, as illustrated in FIG. 24, in case that two eccentricity measurement sensors 120 are applied and a value of an air gap changes over time (dynamic eccentricity), the magnetic flux amount measured from the rotor R may change over time, and both the rotation angle and the magnetic flux amount may change over time. For example, in case that the first eccentricity measurement sensor 120A and the second eccentricity measurement sensor 120B are disposed to be spaced apart from each other with a phase difference of 180 degrees and dynamic eccentricity occurs in the rotor R, the magnetic flux amount graphs of the first eccentricity measurement sensor 120A and the second eccentricity measurement sensor 120B may be formed in opposite directions and different in magnetic flux amount and cycle from the reference value.

Furthermore, at least two or more of the tilt eccentricity, the static eccentricity, and the dynamic eccentricity may occur while overlapping one another. In this case, the type of eccentricity may be analyzed by comparing each of the eccentricity data with the measured data.

The eccentricity measurement system of the present disclosure may include the eccentricity measurement sensor mounted in the motor and configured to measure all the tilt eccentricity, the static eccentricity, and the dynamic eccentricity of the rotor by using a change in magnetic field generated between the rotor and the stator, thereby overcoming a limitation of a reflective laser sensor method in the related art, reducing costs in comparison with the reflective laser sensor in the related art, detecting the eccentricity factor that most significantly affects noise and vibration of the rotary device, detecting a defect at the initial stage of mass production to prevent shipment of potentially defective products, measuring eccentricity caused by abrasion or the like after product durability testing or after prolonged operation of the vehicle to detect in advance a problem, and taking in advance an action such as repair.

In addition, with the above-described eccentricity measurement system, when the eccentricity measurement system is applied to the autonomous vehicles in the future, it is possible to monitor a mechanical state of the rotary device, apply the eccentricity measurement system to a smart rotary device system capable of evaluating a state thereof by using the pre-secured defect level index, and recognize the state of the rotary device in a region imperceptible to humans. Furthermore, the eccentricity measurement system may be applied in a case in which it is difficult to recognize a state of the individual rotary device because of external vibration or noise, such that the eccentricity measurement system may be used to detect and address problems in the electric motor used in urban air mobility (UAM) aircraft in advance.

The technical spirit should not be construed as being limited to the embodiments of the present disclosure. Of course, the scope of application is diverse, and various modifications and implementations may be made by those skilled in the art without departing from the subject matter of the present disclosure claimed in the claims. Accordingly, these improvements and modifications will fall within the scope of the present disclosure as long as they are apparent to those skilled in the art.

### DESCRIPTION OF REFERENCE NUMERALS

1000: Eccentricity measurement system

100: Eccentricity measurement part

110: Sensing board

111: First fixing hole

120: Eccentricity measurement sensor

130: Signal line

140: Circuit pattern

141: Power supply line

141a: Power supply terminal

142: Signal line

142a: Signal output terminal

150: External terminal

200: Sensing housing

210: Center hole

220: Center fixing portion

230: Sensor fixing portion

231: Board insertion groove

232: Interference avoidance groove

233: Signal transmission hole

234: Housing coupling portion

234a: Screw hole

234b: Fixing stepped portion

235: Potting part

236: Housing coupling portion

240: Cover

241: Second fixing hole

120A: First eccentricity measurement sensor

120B: Second eccentricity measurement sensor

S: Stator

R: Rotor

R1: Rotor upper end

R2: Rotor lower end

H: Motor housing

B: Bearing

What is claimed is:

1. An eccentricity measurement system, which is configured to apply to a motor system comprising a stator and a rotor and measures an eccentricity of the rotor, the eccentricity measurement system comprising:
an eccentricity measurement part configured to measure a presence or absence of the eccentricity of the rotor by measuring a change in magnetic field generated between the rotor and the stator; and
a sensing housing comprising:
a first surface in which the eccentricity measurement part is embedded, and
a center hole through a center of the sensing housing so that a rotary shaft of the rotor is fitted into the center hole,
wherein the first surface faces a distal end of the rotor.

2. The eccentricity measurement system of claim 1, wherein the eccentricity measurement part comprises:
a sensing board inserted into the sensing housing; and
an eccentricity measurement sensor embedded in the sensing board.

3. The eccentricity measurement system of claim 2, wherein the sensing housing comprises:
a ring-shaped center fixing portion having the center hole; and
one or more sensor fixing portions protruding radially outward from the center hole and configured such that the eccentricity measurement sensor is embedded in the one or more sensor fixing portions.

4. The eccentricity measurement system of claim 3,
wherein the sensing board is coupled to correspond to a first sensor fixing portion among the one or more sensor fixing portions in a one-to-one manner,
wherein the sensing board is spaced apart from the center fixing portion at a predetermined interval, and
wherein the eccentricity measurement sensor is embedded to correspond to the sensing board in a one-to-one manner.

5. The eccentricity measurement system of claim 4, wherein the eccentricity measurement part further comprises a signal line having a first end electrically connected to the sensing board, and a second end electrically connected to an outside to transmit a sensing signal to the outside, and
wherein the first sensor fixing portion comprises a signal transmission hole penetrating the first sensor fixing portion so that the signal line passes through the signal transmission hole.

6. The eccentricity measurement system of claim 3,
wherein the sensing board is coupled to a second surface of the sensing housing,
wherein the eccentricity measurement sensor includes a plurality of eccentricity measurement sensors,
one or more eccentricity measurement sensors among the plurality of eccentricity measurement sensors are all embedded in the first surface of the sensing housing, and
wherein a region in which a first eccentricity measurement sensor among the plurality of eccentricity measurement sensors is embedded protrudes radially outward so as to correspond to at least one sensor fixing portion among the one or more sensor fixing portions in a one-to-one manner.

7. The eccentricity measurement system of claim 6, wherein the eccentricity measurement part further comprises:
an external terminal electrically connected to the eccentricity measurement sensor and configured to transfer sensing information of the eccentricity measurement sensor to an outside; and
a circuit pattern on a first surface of the eccentricity measurement part to electrically connect the external terminal and the eccentricity measurement sensor.

8. The eccentricity measurement system of claim 7, wherein the circuit pattern comprises:
at least two power supply lines, each comprising two or more power supply terminals configured to supply power to the eccentricity measurement sensor and connected to the eccentricity measurement sensor; and
a signal line comprising two or more signal output terminals configured to output a sensing value of the eccentricity measurement sensor and connected to the eccentricity measurement sensor,
wherein each of the power supply lines and the signal line extend in the same direction, and
wherein the two or more power supply terminals spaced apart from one another at predetermined intervals along the power supply line,
wherein the two or more signal output terminals are spaced apart from one another at predetermined intervals along the signal line.

9. The eccentricity measurement system of claim 7, wherein the sensing board further comprises a first fixing hole through a first region excluding a second region in which the circuit pattern is present,
wherein the sensing housing further comprises a cover on an entirety of the first surface of the sensing housing, and the cover covers the sensing board, and
wherein the cover comprises a second fixing hole penetrating the cover at a position corresponding to the first fixing hole.

10. The eccentricity measurement system of claim 3, wherein at least one sensor fixing portion among the one or more sensor fixing portions comprises a housing coupling portion coupled to a motor housing in which the stator and the rotor are accommodated, and
wherein the housing coupling portion comprises screw holes through the at least one sensor fixing portion and the motor housing.

11. The eccentricity measurement system of claim 3, wherein at least one sensor fixing portion among the one or more sensor fixing portions comprises:
a board insertion groove that is recessed so that the sensing board is inserted into the board insertion groove; and
an interference avoidance groove that is recessed in a cylindrical shape based on a vertex of the board insertion groove.

12. The eccentricity measurement system of claim 3, wherein at least one sensor fixing portion among the one or more sensor fixing portions comprises a housing coupling portion coupled to a motor housing in which the stator and the rotor are accommodated, and
wherein the housing coupling portion comprises a fixing stepped portion placed on a coupling structure of a bearing of the motor housing.

13. The eccentricity measurement system of claim 2, wherein the sensing housing further comprises a flat plate-like potting part configured to cover and protect a first surface of the sensing board.

14. The eccentricity measurement system of claim 2, wherein the eccentricity measurement sensor includes two or more eccentricity measurement sensors, and the eccentricity measurement sensors are disposed to be spaced apart from one another at equal intervals.

15. The eccentricity measurement system of claim 2, wherein the eccentricity measurement sensor includes two or more eccentricity measurement sensors, and the eccentricity measurement sensors are disposed to be spaced apart from one another with a phase difference of 90 degrees.
